(19) United States
(12) Patent Application Publication
(10) Pub. No.: US 2013/0341708 A1
(43) Pub. Date: Dec. 26, 2013

(54) SEMICONDUCTOR DEVICE AND METHOD OF MANUFACTURING THE SEMICONDUCTOR DEVICE

(71) Applicant: Renesas Electronics Corporation, Kawasaki-shi (JP)

(72) Inventor: Wataru Sumida, Kanagawa (JP)

(73) Assignee: Renesas Electronics Corporation

(21) Appl. No.: 13/913,147

(22) Filed: Jun. 7, 2013

(30) Foreign Application Priority Data
Jun. 7, 2012 (JP) 2012-129480

(51) Int. Cl. H01L 29/78; H01L 29/66

(52) U.S. Cl. CPC H01L 29/7827; H01L 29/66666
USPC 257/330; 438/270

(57) ABSTRACT

A low concentration P-type impurity (LCPI) layer situated over a drain layer has an impurity concentration lower than the drain layer. An N-type impurity base layer is situated over the LCPI layer. A gate insulating film is formed on the lateral side of a trench. A bottom insulation film formed to the bottom and lower portion on the lateral side of the trench has a larger thickness than the gate insulating film. A gate electrode is filled in the trench. At a cross section in the direction of the thickness including the bottom of the trench, a profile of the P-type impurity concentration is substantially constant and the difference between the maximum and minimum values is 10% or less of the average value for the maximum and minimum values. Further, the profile has a maximal value and a minimal value situated from the maximal value to the drain layer.

### CROSS-REFERENCE TO RELATED APPLICATIONS

The disclosure of Japanese Patent Application No. 2012-129480 filed on Jun. 7, 2012 including the specification, drawings, and abstract is incorporated herein by reference in its entirety.

### BACKGROUND

The present invention relates to a semiconductor device and a method of manufacturing the semiconductor device and it particularly relates to a semiconductor device having a vertical transistor and a method of manufacturing the semiconductor device.

Semiconductor devices include vertical type transistors. The vertical transistor is used, for example, as a device of controlling high current. The vertical transistor includes those having a trench gate structure. In the trench gate structure, a trench is formed in a semiconductor substrate, a gate insulating film is formed on the lateral side of the trench and a gate electrode is filled in the trench. Transistors having such a trench gate structure are shown, for example, in Japanese Unexamined Patent Application Publications Nos. 2006-344760 and 2003-347545.

Particularly, Japanese Unexamined Patent Application Publication No. 2006-344760 describes that a thick insulating film is formed to the bottom and the lower portion on the lateral side of the trench for moderation of electric fields.

### SUMMARY

The present inventors, as a result of study, have found that when a thick insulating film is formed to the bottom and the lower portion on the lateral side of a trench in a vertical transistor of a P-channel type trench gate structure, resistance of a semiconductor layer situated at the periphery of the trench increases. When the resistance of the semiconductor layer increases, the on-resistance of the vertical transistor increases.

Other subjects and novel features will become apparent in view of descriptions of the present specification and appended drawings.

According to an aspect of this invention, a semiconductor device has a P-type drain layer, a low concentration P-type impurity layer, and an N-type base layer. A trench is formed in the N-type base layer. The lower end of the trench is situated in the low concentration P-type impurity layer. A gate insulating film and a bottom insulating film are formed on the lateral side of the trench. The bottom insulating film is formed to the lower portion of the lateral side of the trench and the bottom of the trench. A gate electrode is filled in the trench. When the thickness of the bottom insulating film at a portion situated to the bottom of the trench is assumed as t_{b}, a profile of the P-type impurity concentration of the low concentration P-type impurity layer at a first cross section, that is, a cross section in the direction of the thickness including the bottom of the trench has 10% or less of a variation range within a range of a distance from the bottom insulating film of 0.5 t_{b} or more to 3.0 t_{b} or less.

According to another aspect of this invention, a first profile which is a profile of the P-type impurity concentration of the low concentration P-type impurity layer has a maximal value within a range of a distance from the bottom insulating film of 0.5 t_{b} or more and 3.0 t_{b} or less.

According to the aspects, increase in the on-resistance of the vertical transistor can be suppressed.

### BRIEF DESCRIPTION OF THE DRAWINGS

FIG. 1A is a plan view illustrating a configuration of a semiconductor device according to a first embodiment;

FIG. 1B is a cross sectional view along with a line A-A′ in FIG. 1A;

FIG. 2 is an enlarged cross sectional view of a region including a bottom insulating film in FIG. 1B;

FIG. 3A is a graph showing a profile of a P-type impurity concentration of a low concentration P-type impurity layer at a cross section along a line B-B′ in FIG. 2 (second cross section);

FIG. 3B is a graph showing a profile of a P-type impurity concentration of a low concentration P-type impurity layer at a cross section along a line C-C′ in FIG. 2 (first cross section);

FIG. 4 is a cross sectional view of a vertical transistor according to a comparative example;

FIG. 5A is a graph showing a profile of a P-type impurity concentration of a low concentration P-type impurity layer at a cross section along a line B-B′ in FIG. 4 (second cross section);

FIG. 5B is a graph showing a profile of a P-type impurity concentration of the low concentration P-type impurity layer at a cross section along a line C-C′ in FIG. 4 (first cross section);

FIG. 6 is a graph showing the result of simulation for a concentration profile of a P-type impurity at a cross section along a line C-C′ in FIG. 2 (first cross section), together with the concentration profile of the comparative example in FIG. 4.

FIG. 7 is a graph showing the result of simulation for a concentration profile of a P-type impurity at a cross section along a line B-B′ in FIG. 2 (second cross section), together with the concentration profile in the comparative example in FIG. 4.

FIG. 8A is a cross sectional view illustrating a method of manufacturing a semiconductor device according to a preferred embodiment;

FIG. 8B is a cross sectional view illustrating the method of manufacturing the semiconductor device according to the preferred embodiment;

FIG. 8C is a cross sectional view illustrating the method of manufacturing the semiconductor device according to the preferred embodiment;

FIG. 9 is a cross sectional view illustrating the method of manufacturing the semiconductor device according to the embodiment;

FIG. 10 is a cross sectional view illustrating the method of manufacturing the semiconductor device according to the preferred embodiment;

FIG. 11A is a cross sectional view illustrating the method of manufacturing the semiconductor device according to the preferred embodiment;

FIG. 11B is a cross sectional view illustrating the method of manufacturing the semiconductor device according to the preferred embodiment;

FIG. 11C is a cross sectional view illustrating the method of manufacturing the semiconductor device according to the preferred embodiment;

FIG. 12 is a graph showing a relation between an injection angle λ of P-type impurity ions to a normal line at the surface of a low concentration P-type impurity layer and a width a in a low concentration region A;

FIG. 13 is a graph showing a relation between on-current Iₒₙ of a vertical transistor and the injection angle λ of impurity ions;

FIG. 14A is a cross sectional view illustrating a structure of a trench in a semiconductor device according to a second embodiment;

FIG. 14B is a cross sectional view illustrating a structure of the trench in the semiconductor device according to the second embodiment;

FIG. 15A is a cross sectional view illustrating a method of manufacturing a semiconductor device according to a third embodiment;

FIG. 15B is a cross sectional view illustrating the method of manufacturing the semiconductor device according to the third embodiment;

FIG. 15C is a cross sectional view illustrating the method of manufacturing a semiconductor device according to the third embodiment;

FIG. 16A is a cross sectional views illustrating a modification of FIG. 15;

FIG. 16B is a cross sectional views illustrating the modification of FIG. 15;

FIG. 16C is a cross sectional views illustrating the modification of FIG. 15; and

FIG. 16D is a cross sectional views illustrating the modification of FIG. 15.

### DETAILED DESCRIPTION

Preferred embodiments of the invention are to be described with reference to the drawings. Throughout the drawings, identical constituent elements carry the same reference numerals for which descriptions are optionally omitted.

### First Embodiment

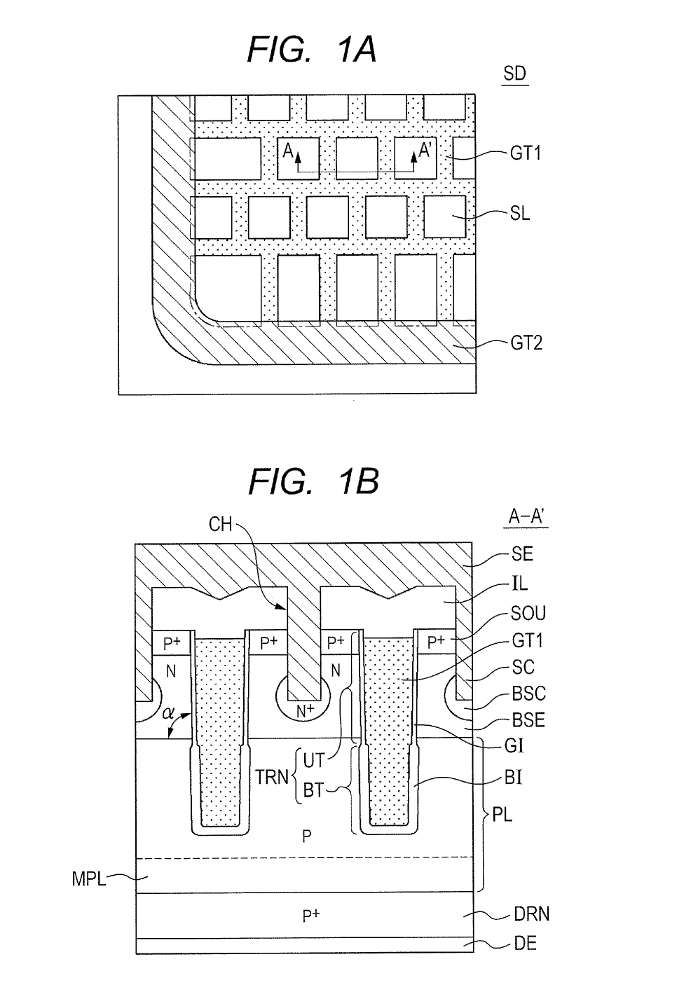

FIG. 1A is a plan view illustrating a configuration of a semiconductor device SD according to a first embodiment. FIG. 1B is a cross sectional view along a line A-A′ in FIG. 1A. The semiconductor device SD has vertical transistors. The vertical transistor has a P-type drain layer DRN, a low concentration P-type impurity layer PL, a base layer BSE, a trench TRN, a gate insulating film GI, a bottom insulating film BI, a gate electrode GT1, and a source layer SOU. The low concentration P-type impurity layer PL is situated over the drain layer DRN and has an impurity concentration lower than that of the drain layer DRN. The base layer BSE is an N-type impurity layer and situated over the low concentration P-type impurity layer PL. The trench DRN is formed in the base layer BSE with the lower end of the trench being situated in the low concentration P-type impurity layer PL. The gate insulating film G1 is formed on the lateral side of the trench TRN. The bottom insulating film BI is formed at the bottom and the lower portion on the lateral side of the trench TRN and has a thickness larger than that of the gate insulating film GI. The gate electrode GT1 is filled in the trench TRN. The source layer SOU is a P-type impurity layer and formed in the base layer BSE to a depth shallower than the base layer BSE. The source layer SOU is situated adjacent to the trench TRN in a plan view.

Then, when the thickness of the bottom insulating film BI at a portion situated to the bottom of the trench TRN is assumed as t_{b}, a first profile of the P-type impurity concentration of the low concentration P-type impurity layer PL is substantially constant at a first cross section in the direction of the thickness including the bottom of the trench TRN within a range of distance from the bottom insulating film BI of 0.5 t_{b} or more and 3.0 T_{b} or less, and has a variation range of 10% or less. Further, the first profile has a maximal value within a range of a distance from the bottom insulating film BI of 0.5 t_{b} or more and 3.0 t_{b} or less. Details are to be described specifically.

In the embodiment, the P-type impurity is, for example, B (boron) and the N-type impurity is, for example, P (phosphorus). However, the N-type impurity may also be other group V elements.

FIG. 1A illustrates a corner of the vertical transistor. As illustrated in the drawing, the vertical transistor has multiple cells SL. Each of the cells SL is surrounded by a gate electrode GT1 and a portion facing the gate electrode GT1 serves as a channel. The multiple cells SL are arranged in a 2-dimensional manner in a plan view. While the cells SL are arranged as a hound's-tooth check pattern in the example of the drawing, arrangement of the cells SL is not restricted to this example. For example, the cells SL may be arranged in a square lattice pattern.

A region in which multiple cells are arranged is surrounded by a gate interconnect GT2. The gate interconnect GT2 is formed of a material identical with the source electrode SE and transmits a gate voltage to the gate electrode GT1. The source electrode SE and the gate interconnect GT2 are formed, for example, of aluminum or an aluminum alloy (for example, Cu-containing aluminum alloy).

As illustrated in FIG. 1B, a semiconductor substrate comprises the drain layer DRN, the low concentration P-type impurity region PL, and the base layer BSE. The semiconductor substrate is formed by epitaxially growing a semiconductor layer that forms the low concentration P-type impurity layer PL and the base layer BSE over the drain layer DRN. In the semiconductor substrate, for example, a low concentration P-type impurity layer PL is epitaxially grown over the drain layer DRN and N-type impurities are implanted into the surface layer of the low concentration P-type layer PL to form the base layer BSE. The drain layer DRN is, for example, a bulk semiconductor. The drain layer DRN, the low concentration P-type impurity layer PL, and the base layer BSE comprise, for example, silicon. The region of the low concentration P-type impurity layer PL in contact with the drain layer DRN is a transition region MPL. P-type impurity concentration in the transition region MPL increases gradually as it approaches the drain layer DRN.

The trench TRN penetrates the base layer BSE. The lower portion of the trench TRN intrudes into the low concentration P-type impurity layer PL. The gate insulating film GI is formed on the sidewall of the trench TRN at a portion facing the base layer BSE and to an upper portion of the sidewall facing the low concentration P-type impurity layer PL. The bottom insulation film BI is formed on the sidewall of the trench TRN in a region where the gate insulating film GI is not formed, that is, in a lower portion facing the low concentration P-type impurity layer PL, and at the bottom of the trench TRN. The bottom insulating film BI serves as a field insulating film. That is, the bottom insulating film BI suppresses lowering of the drain withstanding voltage of the vertical transistor by the concentration of an electric field at the bottom of the trench TRN. When the base layer BSE and the low concentration P-type impurity layer PL are formed of silicon, the gate insulating film G1 and the bottom insulating film BI comprise a silicon oxide film. The angle α of the sidewall of the trench TRN relative to the surface of the base layer BSE is, for example, 85° or more and 87° or less.

A drain electrode DE is formed at the back of the drain layer DRN. The drain electrode DE is formed, for example, of aluminum or an aluminum alloy (for example, Cu-containing aluminum alloy).

An interlayer insulating film IL is formed over the gate electrode GT1. In the example illustrated in the drawing, the interlayer insulating film IL covers the gate electrode GT1 and the source layer SOU. A connection holes CH is formed in the source layer SOU. The lower end of the connection hole CH intrudes into the base layer BSE. A portion of the sidewall of the connection hole CH comprises the source layer SOU. A source electrode SE is formed over the interlayer insulating film IL and a source contact SC is filled inside of the contact hole CH. The source electrode SE and the source contact SC are formed integrally. A portion of the lateral side of the source contact SC is connected to the source layer SOU. That is, the source layer SOU is connected by way of the source contact SC to the source electrode SE.

An N-type base contact layer BSC is disposed in the base layer BSE. The base contact layer BSC is situated below the source layer SOU and has an impurity concentration higher than that of the base layer BSE. The base layer BSE is connected to the source contact SC. That is, the base layer BSE is connected by way of the source contact SC to the source electrode SE.

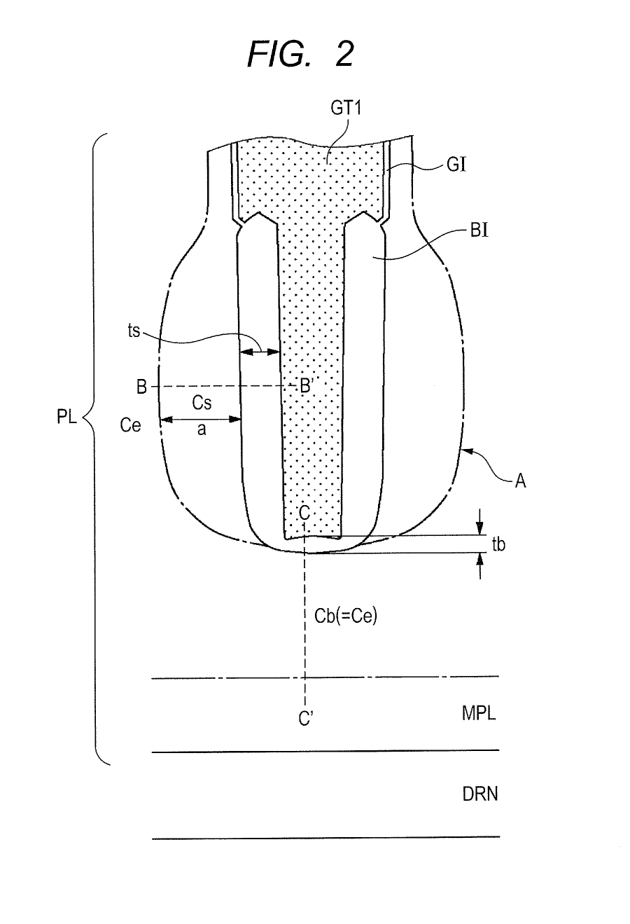

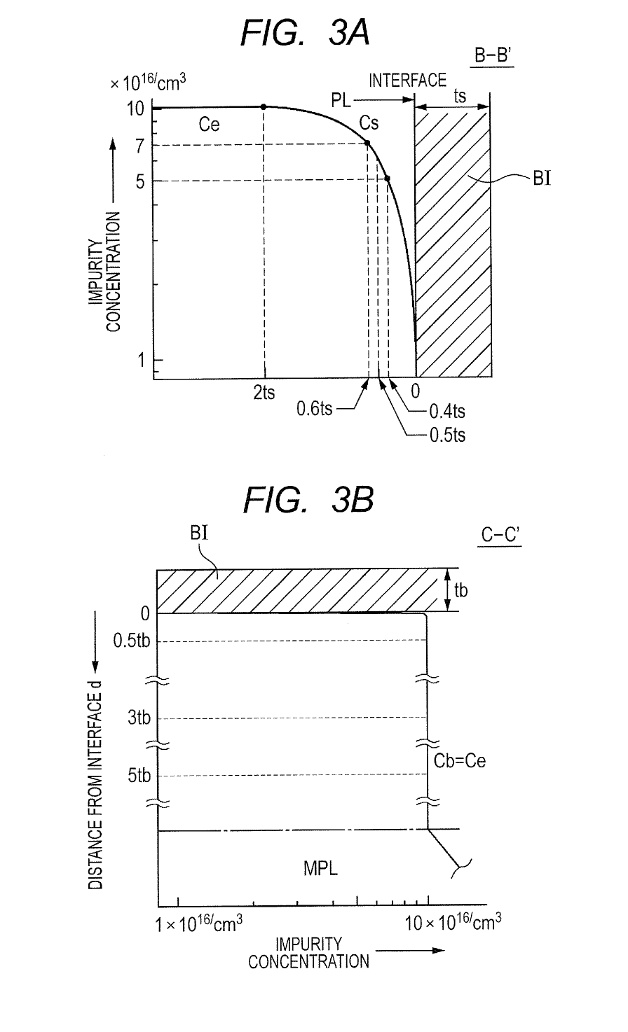

FIG. 2 is an enlarged cross sectional view for a region of FIG. 1B including the bottom insulating film BI. FIG. 3A is a graph showing a profile (second profile) of P-type concentration of the low concentration P-type impurity layer PL at a cross section along a line B-B′ in FIG. 2 (second cross section), that is, a cross section parallel to the surface of the base layer BSE. FIG. 3B is a graph showing a profile (first profile) of P-type impurity concentration of the low concentration P-type impurity layer PL at a cross section along a line C-C′ of FIG. 2 (first cross section), that is, a cross section in the direction of the thickness of the insulating film situated at the bottom of the trench TRN in the bottom insulating film BI.

Generally, P-type impurities tend to be absorbed in a material forming the bottom insulating film BI, for example, silicon oxide. Accordingly, at the periphery of the bottom insulating film BI, the P-type impurities of the low concentration P-type impurity layer PL are absorbed in the bottom insulating film BI. Therefore, a low concentration region A at a further lower impurity concentration is formed in the low concentration P-type impurity layer PL at the periphery of the trench TRN. When the low concentration region A is formed, the on-resistance of the vertical transistor increases.

On the contrary, in the embodiment illustrated in FIG. 2, the impurity concentration of the low concentration P-type impurity layer PL is higher in the portion facing the bottom of the trench TRN than that in other portions. Such an impurity profile is formed, for example, by ion implanting P-type impurities to the trench TRN after forming the trench TRN and before forming the gate electrode GT1. The low concentration region A is not formed to a portion facing the bottom of the trench TRN, or the low concentration region A at a portion facing the bottom of the trench TRN has a width a narrower than that of the low concentration region A at a portion facing the lateral side of the trench TRN. Accordingly, increase in the on-resistance of the vertical transistor can be suppressed.

Specifically, as illustrated in FIG. 3A, it is assumed that the thickness of the bottom insulating film BI as tₛ and the impurity concentration of the low concentration P-type impurity layer PL as Cₛ at a B-B′ cross section in FIG. 2. It is further assumed that the original impurity concentration of the low concentration P-type impurity layer PL, that is, the impurity concentration of the low concentration P-type impurity layer PL in a region spaced apart enough from the bottom insulation film B1 is Cₑ (≈10×10¹⁶/cm³). The impurity concentration Cₛ of the low concentration P-type impurity layer PL is less than Cₑ within a range of 2×tₛ from the interface between the bottom insulating film BI and the low concentration P-type impurity layer PL. For example, at a position of 0.6×tₛ from the interface, the impurity concentration Cₛ is about 0.7 times Cₑ (≈7×10¹⁶/cm³) and the impurity concentration Cₛ at the position of 0.4×tₛ from the interface is about 0.5 times Cₑ (≈5×10¹⁶/cm³). Further, near the bottom insulating film BI, the impurity concentration Cₛ is 0.2 times Cₑ (≈2×10¹⁶/cm³) or less.

Further, the impurity concentration Cₛ of the low concentration P-type impurity layer PL situated at 0.5×tₛ from the interface between the bottom insulating film BI and the low concentration P-type impurity layer PL at the second cross section (≈6×10¹⁶/cm³) is more than 0.5×Cₑ.

On the other hand, as illustrated in FIG. 3B, it is assumed that the thickness of the bottom insulating film BI is t_{b} at a portion situated to the bottom of the trench TRN and the impurity concentration of the low concentration P-type impurity layer PL is C_{b} at a cross section along a line C-C′ in FIG. 2. At the first cross section, the impurity concentration C_{b} of the low concentration P-type impurity layer PL is at a constant value Cₑ (≈10×10¹⁶/cm³) substantially over the entire region. That is, the variation range is 10% or less within a range of 0.5 t_{b} or more and 3.0 t_{b} or less.

Further, the impurity concentration C_{b} of the low concentration P-type impurity layer PL is Cₑ (≈10×10¹⁶/cm³) in a region spaced apart enough from the interface between the bottom insulating film BI and the low concentration P-type impurity layer PL, for example, at a portion spaced apart by 5×t_{b}. Accordingly, the impurity concentration Cₛ of the low concentration P-type impurity layer within a distance of 2×tₛ from the interface between the bottom insulating film B1 and the low concentration P-type impurity layer PL at the second cross section shown in FIG. 3A is lower than the impurity concentration C_{b} (≈10×10¹⁶/cm³) of the low concentration P-type impurity layer PL in a region spaced part by 5×t_{b} from the interface between bottom insulating film B1 and the low concentration P-type impurity layer PL at the first cross section.

The impurity concentration Cₛ of the low concentration P-type impurity layer PL situated at 0.5×tₛ from the interface between the bottom insulating film BI and the low concentration P-type impurity layer PL at the second cross section is lower than the impurity concentration C_{b} of the low concentration P-type impurity layer PL situated at 0.5×t_{b} from the interface between the bottom insulating film BI and the low concentration P-type impurity layer PL at the first cross section (≈10×10¹⁶/cm³), for example, as: C_{b}>1.5×Cₛ (≈1.5×6×10¹⁶/cm³).

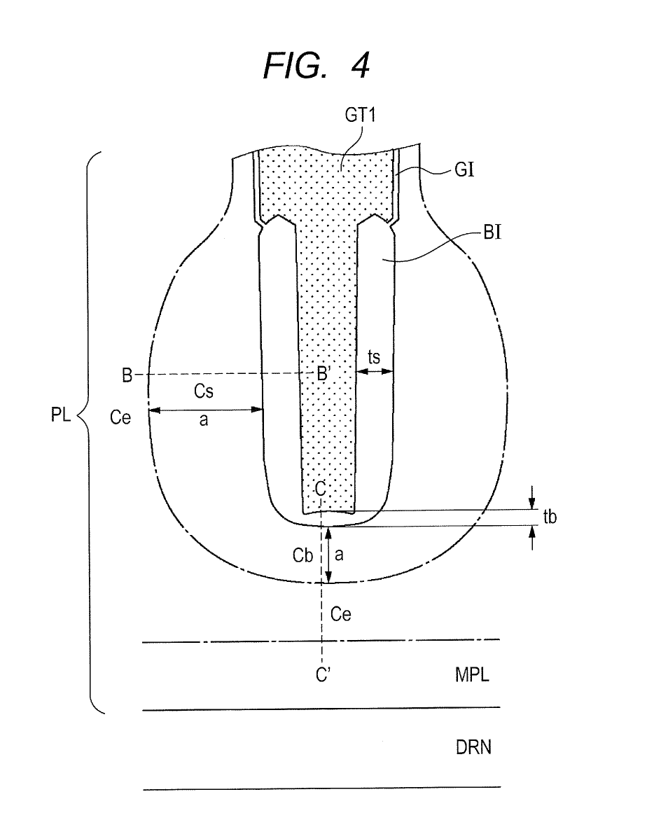

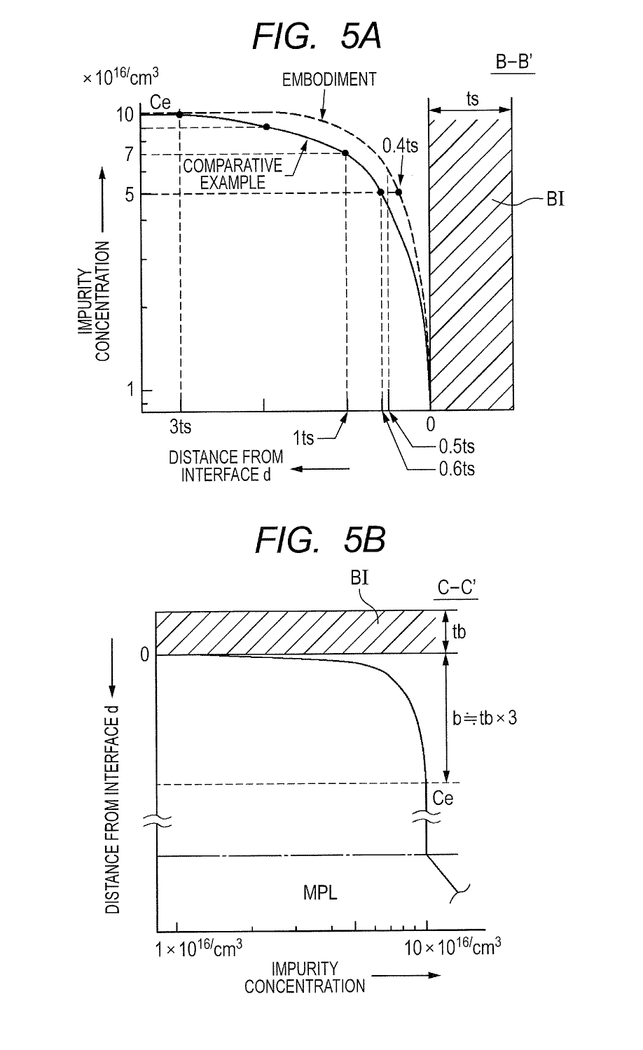

FIG. 4 is a cross sectional view of a vertical transistor according to a comparative example which corresponds to FIG. 2 for the first embodiment. FIG. 5A is a graph showing a profile (second profile) of the P-type impurity concentration in the low concentration type impurity region PL at a cross section along line B-B′ (second cross section) in FIG. 4. FIG. 5B is a graph showing a profile (first profile) of a P-type impurity concentration of the low concentration P-type impurity layer PL at a cross section along a line C-C′ in FIG. 4 (first cross section).

In the comparative example, the impurity concentration of the low concentration P-type impurity layer PL at a portion facing the bottom of the trench TRN is identical with that of other portions (for example, near the lateral side of the trench TRN) before forming the bottom insulating film BI. Accordingly, a low concentration region A is formed also in a portion facing the bottom of the trench TRN. In this case, the on-resistance of the vertical transistor increases.

Specifically, as illustrated in FIG. 5B, the impurity concentration C_{b} of the low concentration P-type impurity layer PL within a range of b≈3×t_{b} from the interface between the bottom insulating film BI and the low concentration P-type impurity layer PL at the first cross section is smaller than Cₑ (≈10×10¹⁶/cm³).

Further, as illustrated in FIG. 5A, the impurity concentration Cₛ of the low concentration P-type impurity layer PL is lower than that of the embodiment illustrated in FIG. 3B (shown by dotted line in FIG. 5A) also at the second cross section. For example, the impurity concentration Cₛ is about 0.7 times Cₑ (≈7×10¹⁶/cm³) at a position of 1×tₛ from the interface and the impurity concentration Cₛ is about 0.5 times of Cₑ (≈5×10¹⁶/cm³) at a position of 0.6×tₛ from the interface.

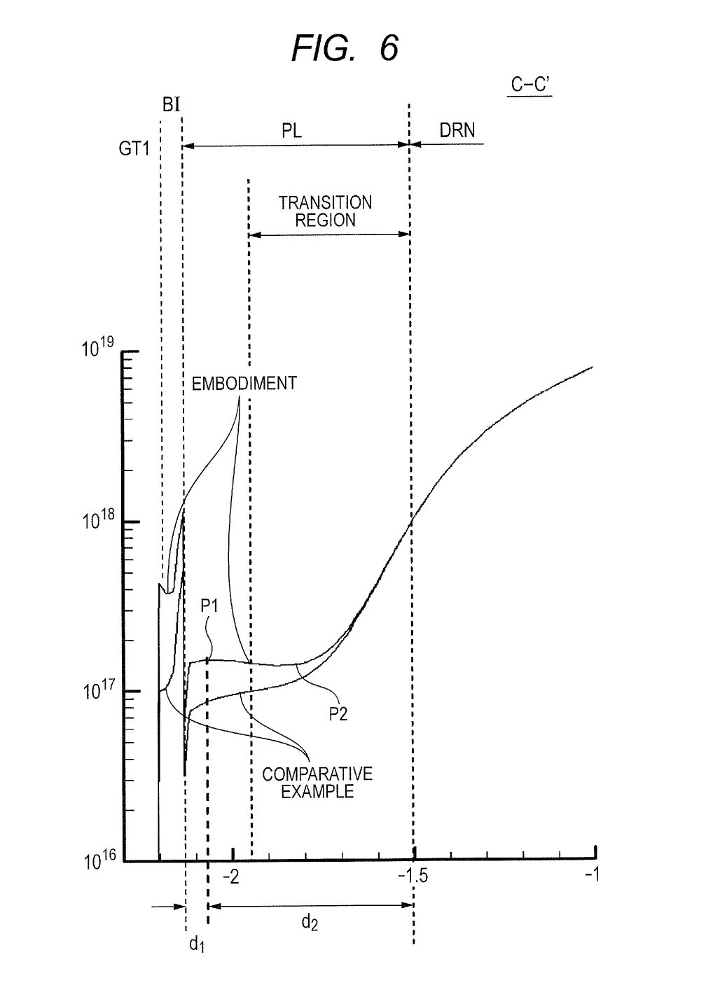

FIG. 6 is a graph showing the result of simulation for the concentration profile of the P-type impurity at a cross section along a line C-C′ of FIG. 2 (first cross section) in this embodiment together with the concentration profile in the comparative example of FIG. 4. In the embodiment illustrated in the drawing, P-type impurities are ion implanted into the trench TRN after forming the trench TRN and before forming the gate electrode GT1 TRN in the semiconductor device SD according to the embodiment.

In the embodiment, the first profile of the low concentration P-type impurity layer PL has a maximal value P1 at a distance from the bottom insulating film BI within a range of 0.5 t_{b} or more and 3.0 t_{b} or less. This is because the P-type impurity ions are implanted into the trench TRN, and the implanted impurities situated near the bottom insulating film BI are absorbed to the bottom insulating film BI. Further, the distance d₁ from the bottom of the trench TRN, that is, the bottom insulating film BI to the maximum value P1 is less than the distance d₂ from the train layer DRN to the maximal value P1.

Further, the first profile has a minimal value P2 situated at a position from the maximal value P1 to the drain layer DRN. This is because the implanted impurity ions are not diffused as far as the portion spaced apart from the bottom insulating film BI.

The difference between the maximal value P1 and the minimal value P2, that is, the variation range of the impurity concentration in the first profile (difference between the maximum value and the minimum value) is 10% or less, for example, 4% or less of the average value for the maximum value and the minimum value. In the example shown in the drawing, the maximum value of the impurity concentration is the maximal value P1 described above and the minimum value is a minimal value P2 described above.

On the other hand, the first profile of the low concentration P-type impurity layer PL according to the comparative example has no maximal value or minimal value and the concentration increases more as it approaches the drain layer DRN.

Both in the embodiment and the comparative example, the concentration of the P-type impurity of the bottom insulating film BI is highest at or near the interface relative to the low concentration P-type impurity layer PL and lowers as it approaches the interface relative to the gate electrode GT1. However, the concentration of the P-type impurity in the bottom insulating film BI gradually increase as it reaches the minimal value near the interface relative to the gate electrode GT1 in this embodiment, whereas the concentration of the P-type impurity in the comparative example gradually lowers till it reaches the interface relative to the gate electrode GT1. The embodiment has such a profile because impurities are introduced additionally.

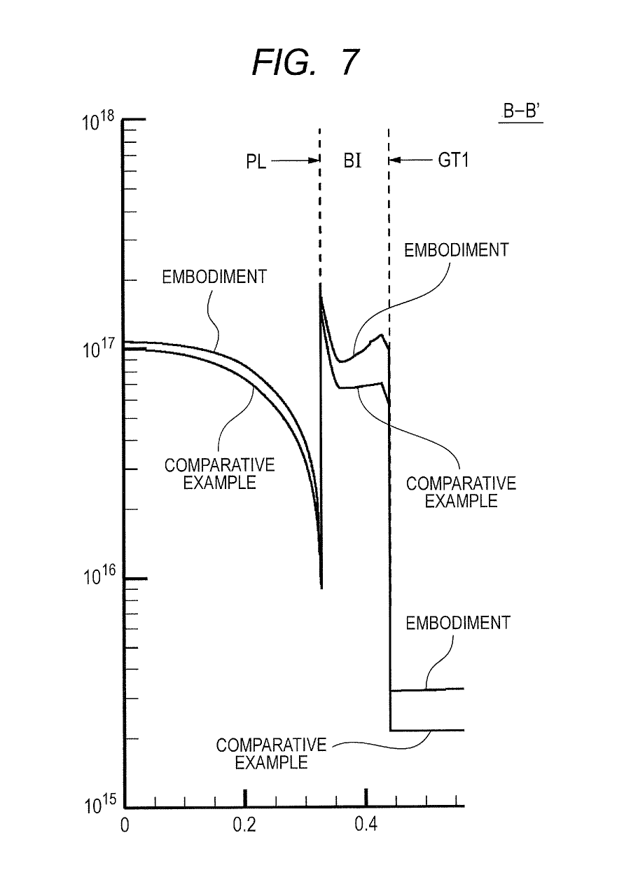

FIG. 7 is a graph showing the result of simulation for the concentration profile (second profile) of the P-type impurity at a cross section along a line B-B′ in FIG. 2 (second cross section) together with the concentration profile of the comparative example of FIG. 4.

In both of the embodiment and the comparative example, the impurity concentration of the low concentration P-type impurity layer PL is lowered as it approaches the bottom insulating film BI. Further, the concentration of the P-type impurity in the bottom insulating film BI shows a trend identical with that of the first profile illustrated in FIG. 6. In the embodiment, the concentration of the P-type impurity in the bottom insulating film BI at the second cross section (9×10¹⁶/cm³ to 2×10¹⁷/cm³) is lower than the concentration of the P-type impurity in the bottom insulating film BI at the first cross section (4×10¹⁷/cm³ to 1×10¹⁸/cm³)

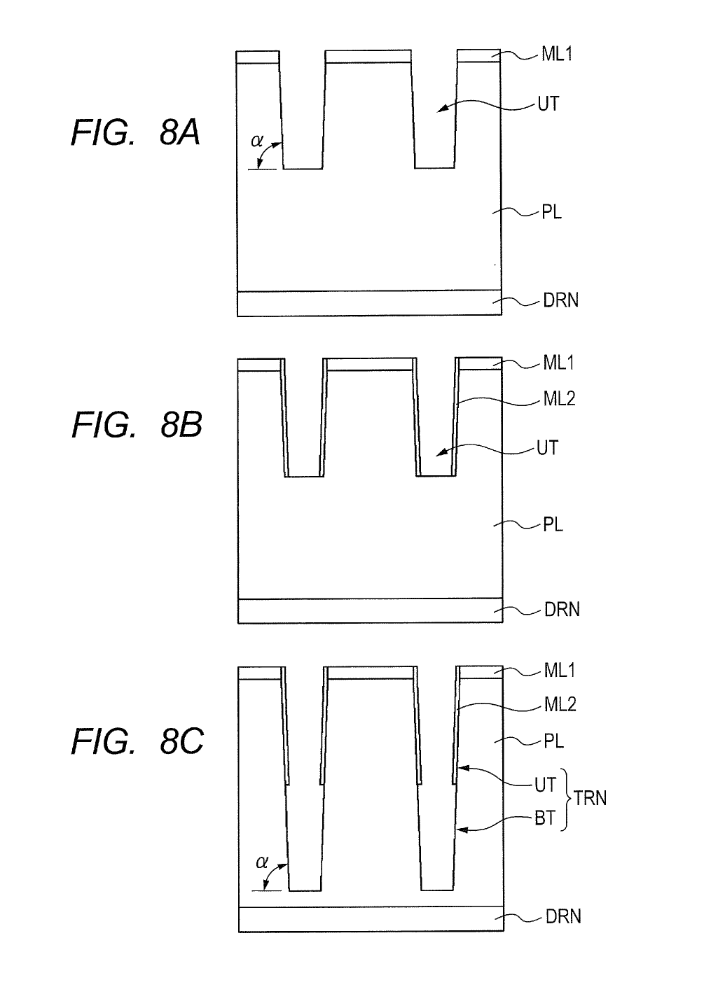

FIG. 8 to FIG. 11 are cross sectional views illustrating a method of manufacturing a semiconductor device according to this embodiment. The method of manufacturing the semiconductor device is as outlined below. At first, a semiconductor substrate including a drain layer DRN and a low concentration P-type impurity layer PL is formed. Then, a trench TRN is formed in the semiconductor substrate. Then, a gate insulating film GI and a bottom insulating film BI are formed on the lateral side of the trench TRN. A gate electrode GT1 is filled in the trench TRN. Then, a source layer SOU is formed to the semiconductor substrate. The method includes a step of forming a base layer BSE to the semiconductor substrate before the step of forming the source layer SOU. Further, the method includes a step of implanting P-type impurities into the low concentration P-type impurity layer PL situated at the periphery of the bottom of the trench TRN before the step of filling the gate electrode GT1 to the trench TRN. This is to be described more specifically.

At first, a semiconductor substrate which forms a drain layer DRN is provided. The semiconductor substrate previously contains P-type impurities at high concentration. Then, as illustrated in FIG. 8A, the low concentration P-type impurity layer PL is epitaxially grown over the drain layer DRN. Then, a first mask film ML1 is formed over the low concentration P-type impurity layer PL. The first mask film ML1 has an opening at a region where the trench TRN is to be formed. When the low concentration P-type impurity layer PL comprises a silicon layer, the first mask film ML1 has, for example, a configuration in which a silicon nitride film is stacked over a silicon oxide film. Then, the low concentration P-type impurity layer PL is anisotropically etched (for example, by anisotropic dry etching) by using the first mask film ML1 as a mask. Thus, a first trench UT is formed in the low concentration P-type impurity layer PL. The first trench UT forms an upper portion of the trench TRN and the top end of the first trench is situated below a portion which forms the base layer BSE.

In this step, the lateral side of the first trench UT cab be inclined by using a carbon-containing gas, for example, CBrF₃ as an etching gas. Specifically, an organic material is formed by reaction of carbon contained in the etching gas in plasma. The organic material is deposited on the lateral side of the first trench UT and serves as a mask film. Accordingly, the lateral side of the first trench UT is inclined in a direction in which the width of the first trench UT is narrowed downwardly. The inclined angle α on the lateral side of the first trench UT can be controlled by controlling the etching condition in this step. Subsequently, a thermal oxide film (not illustrated) is formed on the sidewall of the first trench UT and the thermal oxide film is removed subsequently. Thus, layers undergoing etching damages are removed.

Then, as illustrated in FIG. 8B, a second mask film ML2 is formed on the lateral side and at the bottom of the first trench UT. Then, the second mask film ML2 situated at the bottom of the first trench UT is removed by anisotropic etching. The second mask film ML2 is, for example, a silicon nitride film.

Then, as illustrated in FIG. 8C, the low concentration P-type impurity layer PL is anisotropically etched by using the first mask film ML1 and the second mask film ML2 as a mask. Thus, the bottom of the first trench UT is further etched to form a second trench BT. The trench TRN is formed as described above.

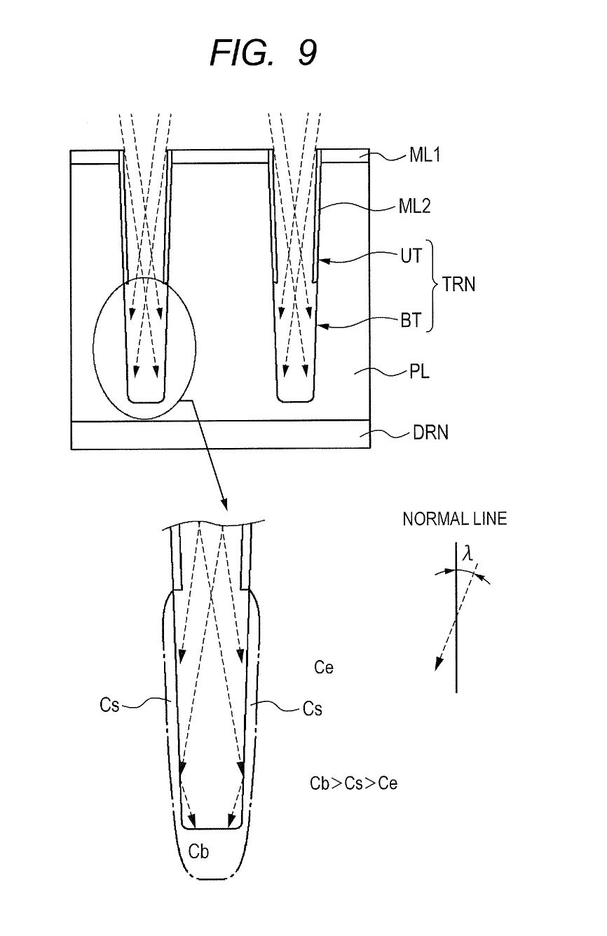

Then, as illustrated in FIG. 9, P-type impurities, for example, B (boron) are ion implanted into the second trench BT of the trench TRN by using the first mask film ML1 and the second mask film ML2 as a mask. Thus, P-type impurities are additionally introduced into the low concentration P-type impurity layer PL situated at the periphery of the second trench BT. That is, in this embodiment, the step of additionally introducing the P-type impurities into the low concentration P-type impurity layer PL is performed after the step of forming the trench TRN and before the step of forming a gate insulating film GI and a bottom insulating film BI. According to the method, increase in the cost due to the additional introduction of the P-type impurities into the low concentration P-type impurity layer PL can be suppressed. The first mask film ML1 and the second mask film ML2 can be used suitably both as the etching mask in the step of FIG. 8C and as an ion implantation mask in the step of FIG. 9.

In this embodiment, the lateral side of the first trench UT is covered by the second mask film ML2 at the timing of ion implantation of P-type impurities into the trench TRN. Accordingly, the impurity concentration of the low concentration P-type impurity layer PL situated at the periphery of the first trench UT less increases. Accordingly, introduction of the P-type impurities into the base layer BSE can be suppressed.

In this embodiment, the implantation angle λ of implanting the P-type impurity ions to the normal line at the surface layer of the low concentration P-type impurity layer PL is preferably 6° or more and 10° or less. The reason is to be described later.

Further, in this embodiment, the angle of inclination of the lateral side of the first trench UT and the second trench BT to the normal line at the surface layer of the low concentration P-type impurity layer PL (90°−α) is preferably less than the angle of implanting the P-type impurities described above. Since a portion of the impurities is adsorbed to the sidewall of the second trench BT as shown in the enlarged view of FIG. 9, excess increase in the impurity concentration of the low concentration P-type impurity layer PL situated at the bottom of the second trench BT can be suppressed. As a result, the impurity concentration of the low concentration P-type impurity layer PL at the periphery of the trench TRN is highest in a portion situated to the bottom of the second trench BT and next to the highest in a portion situated on the sidewall of the second trench BT (C_{b}>Cₛ>Cₑ). In this step, Cₑ is substantially equal with the impurity concentration of the low concentration P-type impurity layer PL upon epitaxial drawing.

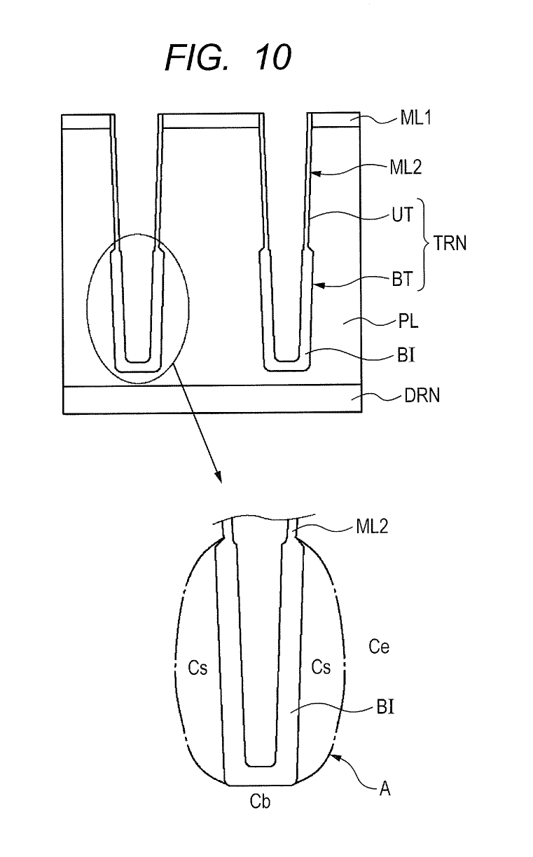

Then, as illustrated in FIG. 10, the low concentration P-type impurity layer PL is thermally oxidized by using the first mask film ML1 and the second mask film ML2 as a mask. Thus, a bottom insulating film BI is formed on the lateral side and at the bottom of the second trench BT (first thermal oxidation). The heat treatment temperature in this step is, for example, at 960° C. or higher and 1,000° C. or lower. In this step, a portion of the P-type impurities contained in the low concentration P-type impurity layer PL is absorbed to the bottom insulating film BI at the periphery of the lateral side and at the periphery on the bottom of the second trench BT. Thus, a low concentration region A is formed. However, in this embodiment, as shown in FIG. 9, P-type impurities are additionally introduced into the low concentration P-type impurity layer PL situated at the periphery on the lateral side and at the periphery at the bottom of the second trench BT. Accordingly, the width of the low concentration region A is decreased. Therefore, increase in the on-resistance of the vertical transistor can be suppressed.

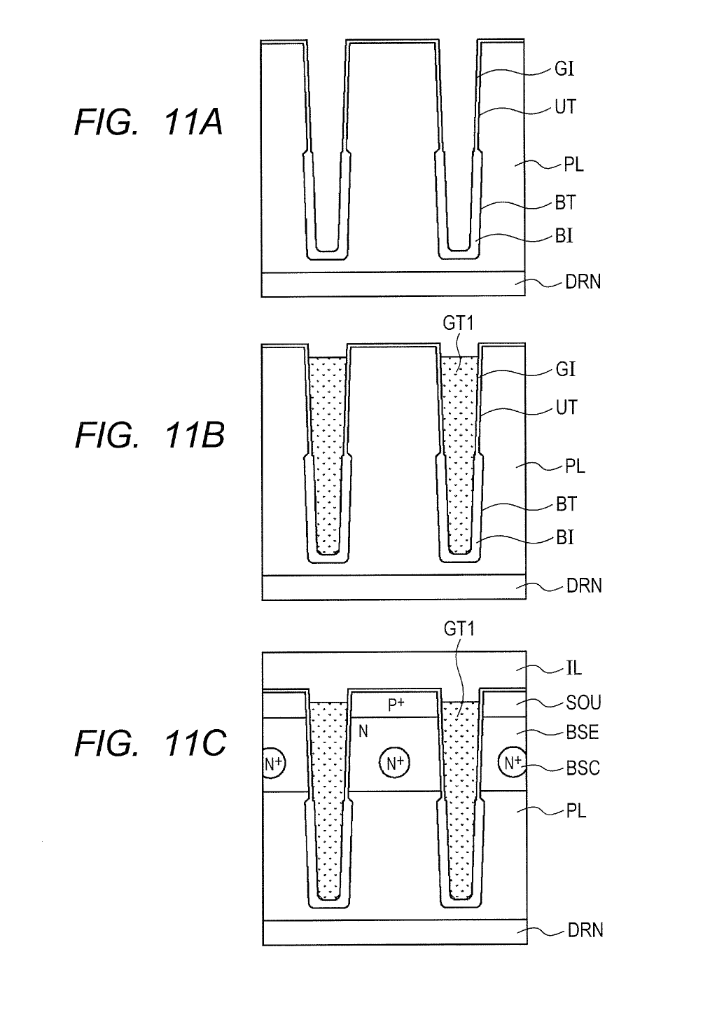

Then, as illustrated in FIG. 11A, the first mask film ML1 and the second mask film ML2 are removed. Then, the low concentration P-type impurity layer PL is thermally oxidized (second thermal oxidation). Thus, a gate insulating film GI is formed on the lateral side of the first trench UT. In this step, the bottom insulating film BI is also grown by thermal oxidation. Therefore, the thickness of the bottom insulating film BI is larger than that of the gate insulating film GI. The heat treatment temperature in the second thermal oxidation is preferably lower than the heat treatment temperature in the first thermal oxidation. The heat treatment temperature in the second thermal oxidation is, for example, at 880° C. or higher and 920° C. or lower. Thus, thermal load applied on the low concentration P-type impurity layer PL is decreased and change of the profile of the impurity concentration of the low concentration P-type impurity layer PL can be suppressed.

Then, as illustrated in FIG. 11B, a conductive film, for example, a polysilicon film which forms a gate electrode GT1 is formed in the inside of the trench TRN and over the low concentration P-type impurity layer PL. Then, the conductive film is removed selectively. Thus, the gate electrode GT1 is formed. In this step, the upper surface of the gate electrode GT1 is preferably lower than the upper surface of the low concentration P-type impurity layer PL.

Then, as illustrated in FIG. 11C, a mask pattern (not illustrated) is formed over the low concentration P-type impurity layer PL and the gate electrode GT1, and N-type impurities, for example, P (phosphorus) are ion implanted into the low concentration P-type impurity layer PL. Thus, a base layer BSE is formed to the surface layer of the low concentration P-type impurity layer PL. Then, the mask pattern is removed.

Then, a mask pattern (not illustrated) is formed over the base layer BSE and the gate electrode GT1, and N-type impurities, for example, P (phosphorus) are ion implanted into the base layer BSE by using the mask pattern as a mask. Thus, a base contact layer BSC is formed in the base layer BSE. Then, the mask pattern is removed.

Then, a mask pattern (not illustrated) is formed over the base layer BSE, the gate electrode BT1, and a gate interconnect GT2, and P-type impurities, for example, B (boron) are ion implanted into the base layer BSE by using the mask pattern as a mask. Thus, a source layer SOU is formed in the surface layer of the base layer BSE. Then, the mask pattern is removed. Then, an interlayer insulating film IL is formed.

Then, the gate interconnect GT2 and the source electrode SE illustrated in FIG. 1 are formed and, further, the drain electrode DE is formed.

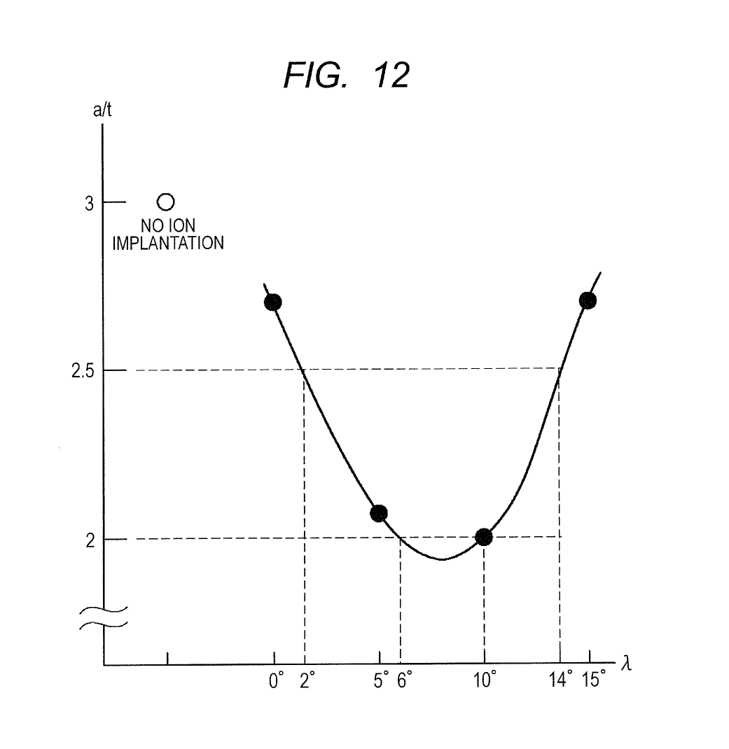

FIG. 12 is a graph showing a relation between the implantation angle λ of the P-type impurity ions relative to the normal line at the surface of the low concentration P-type impurity layer PL and a width a of the low concentration region A. The result shown in the drawing was obtained by simulation. In this drawing, (maximum width of the low concentration region A on the lateral side of the second trench BT)/(thickness tₛ of the bottom insulating film BI on the lateral side of the second trench BT) was used as an index showing the width a of the low concentration region A.

In view of the graph, it can be seen that the maximum value for the width a of the low concentration region A is reduced by implanting impurity ions to the bottom and the sidewall of the trench TRN compared with a case of not implanting the impurity ions. For example, when the implantation angle of the impurity ions is 2° or more and 14° or less, the maximum value for the width a of the low concentration region A is 2.5 times or less the thickness tₛ of the bottom insulating film BI on the lateral side of the second trench BT. Particularly, when the implantation angle of the impurity ions is 6° or more and 10° or less, the maximum value for the width a of the low concentration region A is twice or less the thickness tₛ of the bottom insulating film BI on the lateral side of the second trench BT (for example, 70% or less when the impurity ions are not implanted).

If the implantation angle of the impurity ions is 5° or less, the impurity concentration of the low concentration P-type impurity layer PL situated at the bottom of the trench TRN increases excessively. In this case, the drain withstanding voltage of the vertical transistor is lowered. Also in this view point, the implantation angle of the impurity ions is preferably 6° or more.

The upper limit of the implantation angle of the impurity ions is determined also by the depth of the trench TRN. This is because the impurity ions do not reach as far as the bottom of the trench TRN if the implantation angle is excessively large.

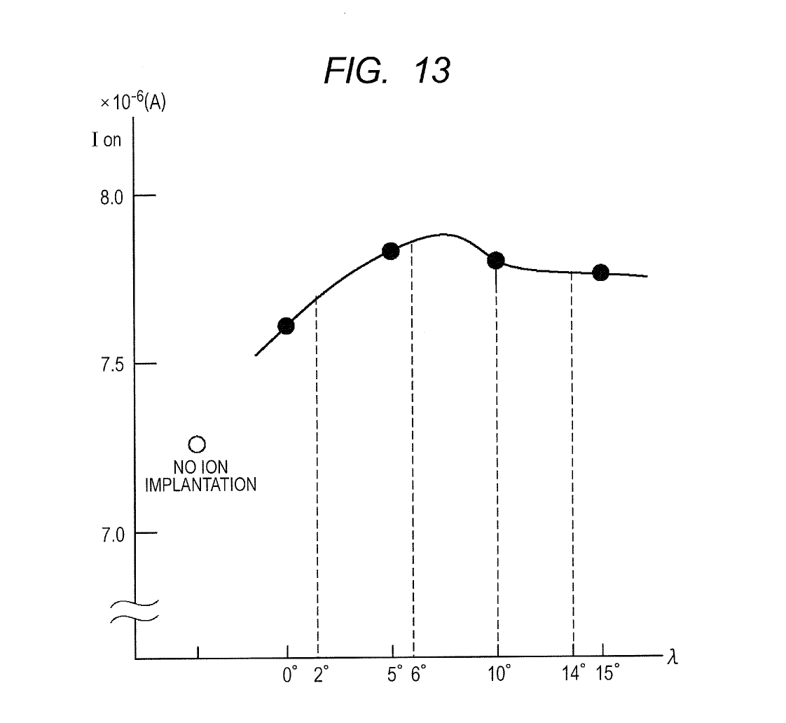

FIG. 13 is a graph showing a relation between the on-current Ion of the vertical transistor and the implantation angle λ of the impurity ions. The result shown in the graph was obtained by simulation. In view of the graph, it can be seen that the on-current of the vertical transistor is increased by implanting impurity ions to the bottom and the sidewall of the trench TRN compared with the case of not implanting the impurity ions. According to the result of the simulation, the on-current of the vertical transistor is greater by about 8% than in a case of not implanting the impurity ions.

As described above, according to this embodiment, impurity ions are introduced into the low concentration P-type impurity layer PL situated at the bottom and on the sidewall of the trench TRN. As a result, the low concentration region A is not formed or the low concentration region A is decreased in a portion facing the bottom of the trench TRN. Accordingly, increase in the on-resistance of the vertical transistor can be suppressed to increase the on-current of the vertical transistor. By the introduction of the impurity ions, the maximal value P1 and the minimal value P2 situated at a position from the maximal value to the drain layer DRN are formed in the profile (first profile) of the low concentration P-type impurity layer PL at a cross section along a line C-C′ in FIG. 2. Since the difference between the maximal value and the minimal value is 10% or less of the average value for the maximal value and the minimal value, it can be said that the impurity concentration is substantially constant in the first profile.

The P-type impurities are additionally introduced into the low concentration P-type impurity layer PL only in the portion situated at the periphery of the trench TRN in a plan view. Therefore, lowering of the gate withstanding voltage of the vertical transistor can be suppressed more than the case of increasing the P-type impurity concentration over the entire low concentration P-type impurity layer PL situated at a depth identical with that of the second trench BT.

### Second Embodiment

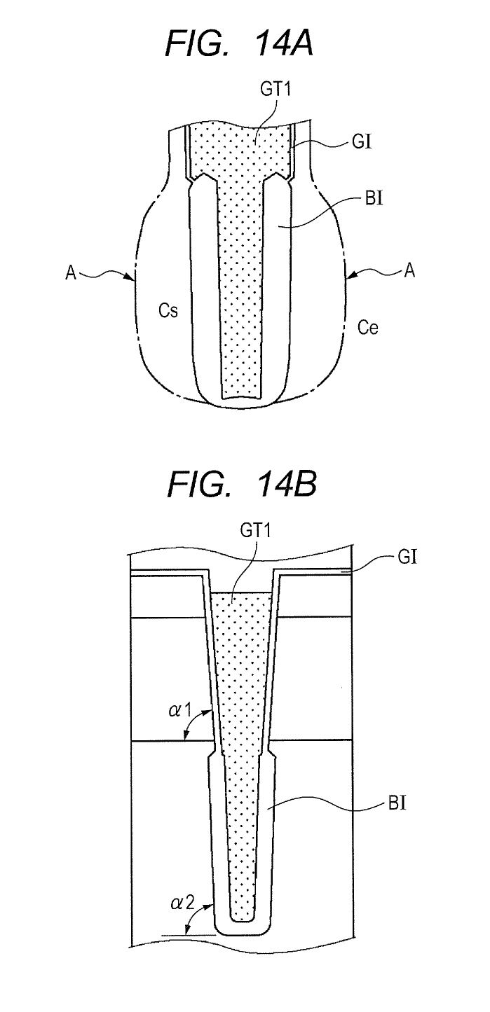

FIGS. 14A and 14B are cross sectional views illustrating a structure of a trench TRN in a semiconductor device SD according to a second embodiment. In the embodiment illustrated in the drawing, the trench TRN comprises a first trench UT and a second trench BT in the same manner as in the first embodiment. An angle α₁ of the lateral side of the first trench UT to the surface of the base layer BSE is smaller than an angle α₂ of the lateral side of the second trench BT to the surface of the base layer BSE. For example, the angle α₁ is 85° or more and 87° or less and the angle α₂ is 87° or more and 89° or less.

According to this embodiment, the same effect as that of the first embodiment can be obtained. Further, since the angle α₁ is smaller than the angle α₂, when the impurity ions are implanted into the lateral side and the bottom of the second trench BT, inhibition of impurity ions by the lateral side of the first trench UT can be suppressed. Further, the angle α₁ and the angle α₂ can be made different by controlling the etching condition. For example, a method of etching by using a carbon-containing reaction gas CBrF₃ is used. In this method, carbon synthesizes an organic material (usually referred to as deposition) in plasma, which serves as an etching mask for the lateral side of the trench and the angle of inclination is formed on the lateral side along with progress of etching. As the amount of carbon is larger, the angle of inclination is larger.

### Third Embodiment

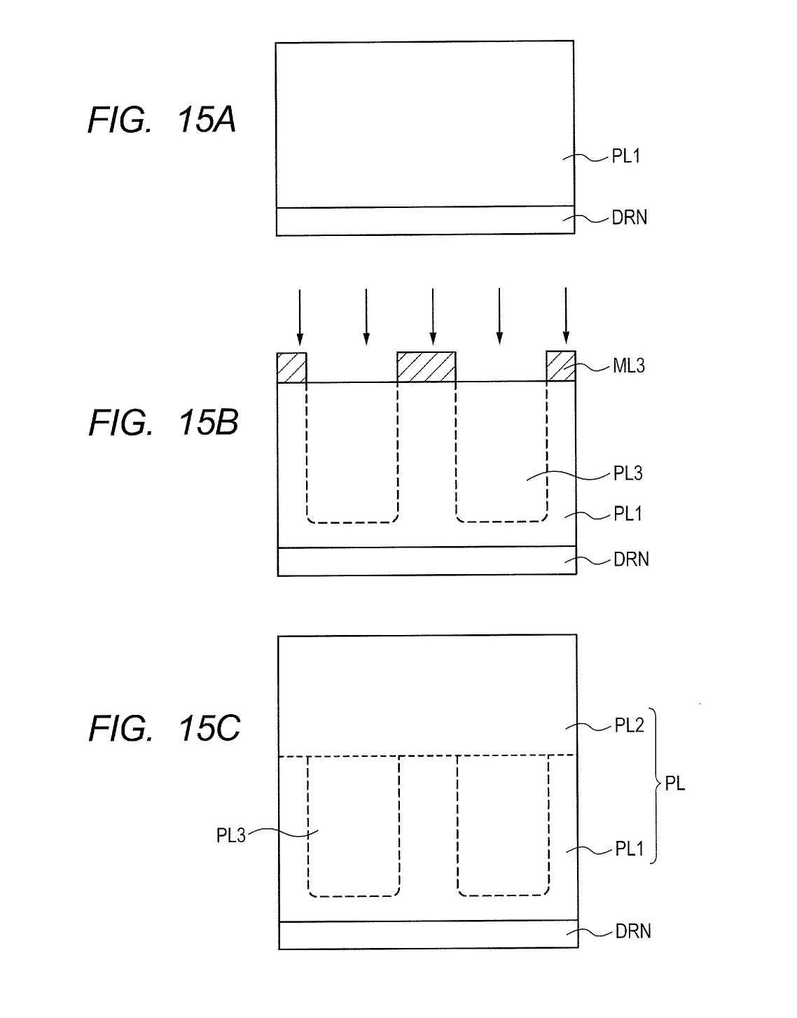

FIG. 15A to FIG. 15C are cross sectional views showing a method of manufacturing a semiconductor device SD according to a third embodiment. This embodiment is identical with the method of manufacturing the semiconductor device SD according to the first embodiment excepting the timing of implanting ions of P-type impurities into the low concentration P-type impurity layer PL.

At first, as illustrated in FIG. 15A, a low concentration P-type impurity layer PL1 which form a lower layer of a low concentration P-type impurity layer PL is epitaxially grown over a drain layer DRN.

Then, as illustrated in FIG. 15B, a third mask film ML3 is formed over the low concentration P-type impurity layer PL1. The third mask film ML3 has an opening. The opening includes, in the inside thereof, a region which forms a trench TRN and the periphery thereof in a plan view. Then, P-type impurities are ion implanted into the low concentration P-type impurity layer PL1 using the third mask film ML3 as a mask. Thus, an impurity addition region PL3 is formed in the low concentration P-type impurity layer PL1. The impurity addition region PL3 is situated in a region where a second trench BT is formed and at the periphery thereof.

Then, as illustrated in FIG. 15C, a low concentration P-type impurity layer PL2 is epitaxially grown over the low concentration P-type impurity layer PL1. The thickness of the low concentration P-type impurity layer PL1 is about identical with the depth of the first trench UT. Thus, a low concentration P-type impurity layer PL is formed.

Subsequent steps are identical with those of the first or second embodiment excepting that the step of implanting impurity ions into the trench TRN (FIG. 9) is not present.

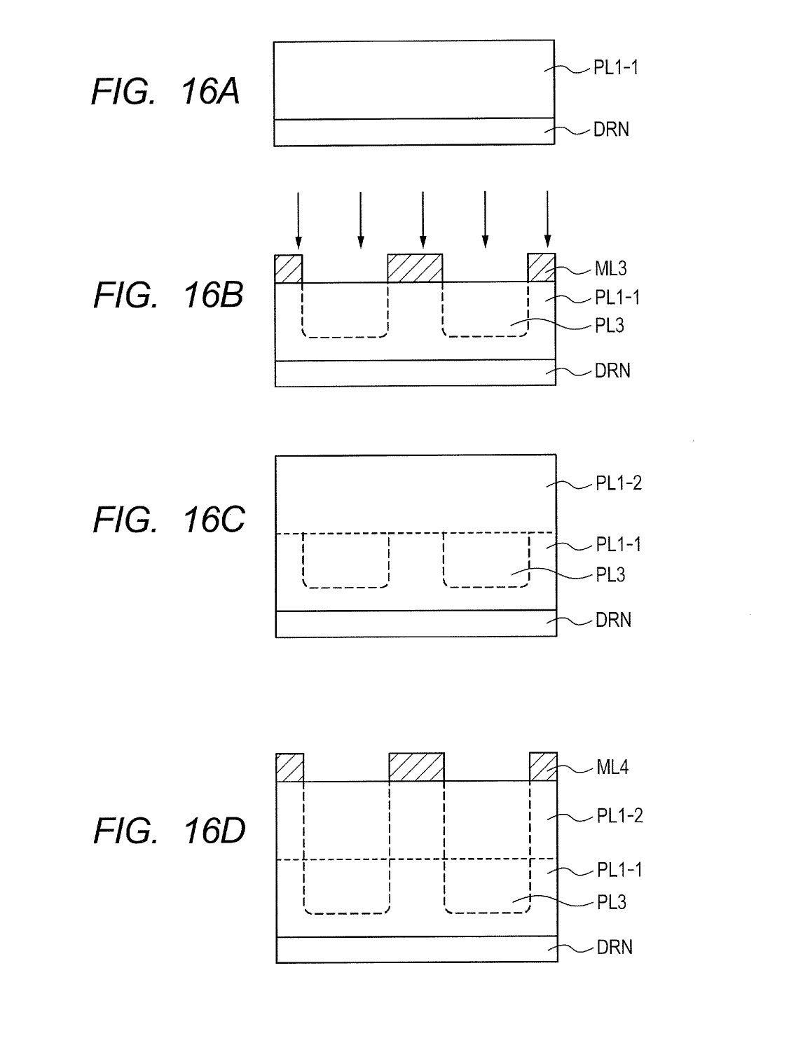

As illustrated in each of FIGS. 16A to 16D, the low concentration P-type impurity layer PL1 may be formed being divided into multiple layers (low concentration P-type impurity layer PL1-1, low concentration P-type impurity layer PL1-2, etc.) and an impurity addition region PL3 may be formed on every formation of the respective layers.

Also in this embodiment, the same effect as in the first or the second embodiment can be obtained.

While the inventions made by the present inventors have been described specifically with reference to the preferred embodiments, it will be apparent that the present invention is not restricted to the embodiments described above but can be modified variously within a range not departing the gist thereof.

What is claimed is:

1. A semiconductor device comprising:
a P-type drain layer;
a low concentration P-type impurity layer formed over the drain layer and having an impurity concentration lower than that of the drain layer;
an N-type base layer situated over the low concentration type impurity layer;
a gate insulating film, formed on the lateral side of a trench which is formed in the base layer with the lower end thereof being situated in the low concentration P-type impurity layer;
a bottom insulating film formed at the bottom and to a lower portion on the lateral side of the trench and having a thickness larger than that of the gate insulating film;
a gate electrode filled in the trench; and
a P-type source layer formed in the base layer to a depth less than the base layer and situated adjacent to the trench in a plan view,
wherein, when the thickness of the bottom insulating film in a portion situated to the bottom of the trench is assumed as t_{b}, a profile of the P-type impurity concentration of the low concentration P-type impurity layer at a first cross section which is a cross section in the direction of the thickness including the bottom of the trench has 10% or less of a variation range within a range of a distance from the bottom-insulating film of 0.5 t_{b} or more and 3.0 t_{b} or less.

2. A semiconductor device comprising:
a P-type drain layer;
a low concentration-P-type impurity layer formed over the drain layer and having an impurity concentration lower than that of the drain layer;
an N-type base layer situated over the low concentration P-type impurity layer;
a gate insulating film formed on the lateral side of a trench, which is formed in the base layer with the lower end thereof being situated in the low concentration P-type impurity layer;
a bottom insulating film formed at the bottom and to a lower portion on the lateral side of the trench and having a thickness larger than that of the gate insulating film;
a gate electrode filled in the trench; and
a P-type source layer formed in the base layer to a depth less than the base layer and situated adjacent to the trench in a plan view,
wherein, when the thickness of the bottom insulating film at a portion situated to the bottom of the trench is assumed as t_{b}, a first profile which is a profile of the P-type impurity concentration of the low concentration P-type impurity layer at a first cross section which is a cross section in the direction of the thickness including the bottom of the trench has a maximal value within a range of a distance from the bottom insulating film of 0.5 t_{b} or more and 3.0 t_{b} or less.

3. The semiconductor device according to claim 2, wherein
the first profile has a minimal value at a position from the maximum value to the drain layer.

4. The semiconductor device according to claim 3, wherein
the difference between the maximal value and the minimal value is 10% or less, of the average value for the maximal value and the minimal value.

5. The semiconductor device according to claim 1, wherein
when the thickness of the bottom insulating film including the lower portion of the lateral side of the trench at a second cross section which is a cross section parallel to the surface of the base layer is assumed as tₛ, the impurity concentration Cₛ of the low concentration P-type impurity layer situated at a position within 2×tₛ from the interface between the bottom insulating film and the low concentration P-type impurity layer is lower than the impurity concentration Cₑ of the low concentration P-type impurity layer situated at a position of 5×t_{b} from the interface between the bottom insulating layer and the low concentration P-type impurity layer to the drain layer at the first cross section.

6. The semiconductor device according to claim 5, wherein the impurity concentration Cₛ of the low concentration P-type impurity layer situated at a position of 0.5×tₛ from the interface between the bottom insulating film and the low concentration P-type impurity layer at the second cross section is higher than 0.5×Cₑ.

7. The semiconductor device according to claim 1, wherein when the thickness of the bottom insulating film including the lower portion on the lateral side of the trench at a second cross section which is a cross section parallel to the surface of the base layer is assumed as tₛ, and the thickness of the bottom insulating layer at the first cross section is assumed as t_{b}, the P-type impurity concentration Cₛ of the low concentration P-type impurity layer situated at a position of 0.5×tₛ from the interface between the bottom insulating film and the low concentration P-type insulating layer at the second cross section is lower than the impurity concentration C_{b} of the low concentration P-type impurity layer situated at a position of 5×t_{b} from the interface between the bottom insulating layer and the low concentration P-type impurity layer to the drain layer at the first cross section.

8. The semiconductor device according to claim 7, wherein
C_{b}>1.5×Cₛ.

9. The semiconductor device according to claim 1, wherein
the low, concentration P-type impurity layer is a silicon layer and contains B (boron) as the P-type impurity.

10. The semiconductor device according to claim 1, wherein
the concentration of the P-type impurity in the bottom insulating film at the first cross section is higher than the concentration of the P-type impurity in the bottom insulating film at the second cross section which is a cross section parallel to the surface of the base layer.

11. A method of manufacturing a semiconductor device including the steps of:
forming a semiconductor substrate comprising a P-type drain layer and a low concentration P-type impurity layer situated over the drain layer and having an impurity concentration lower than that of the drain layer;
forming a trench in the semiconductor substrate;
forming a gate insulating film on the lateral side of the trench and forming a bottom insulating film of a thickness larger than that of the gate insulating film to the bottom and the lower portion on the lateral side of the trench;
filling a gate electrode in the trench; and
forming a P-type source layer situated adjacent to the trench in a plan view, and having
a step of forming an N-type base layer situated over the low concentration P-type impurity layer to the semiconductor substrate before the step of forming the source layer, in which
the bottom of the trench is situated in the low concentration P-type impurity layer, and having
a step of implanting P-type impurities into the low concentration P-type impurity layer situated at the periphery of the lower portion of the lateral side and the bottom of the trench before the step of filling the gate electrode.

12. The method of manufacturing a semiconductor device according to claim 11, wherein
the step of implanting the impurities into the low concentration P-type impurity layer is performed after the step of forming the trench and before the step of forming the gate insulating film and the bottom insulating film.

13. The method of manufacturing a semiconductor device according to claim 12, wherein
the step of forming the trench includes the steps of;
forming a first mask film having an opening over a layer which forms the base layer, and etching the layer which forms the base layer by using the first mask film as a mask thereby forming a first trench as an upper portion of the trench,
covering the lateral side of the first trench by a second mask film, and
etching the bottom of the first trench by using the second mask film as a mask thereby forming the lower portion of the trench, in which
the step of implanting the impurities into the low concentration P-type impurity layer is a step of implanting impurities into the trench while leaving the first mask film and the second mask film as they are.

14. The method of manufacturing a semiconductor device according to claim 13, wherein
in the step of implanting the impurities into the low concentration P-type impurity layer, the angle of implanting the impurities relative to a normal line at the surface of the low concentration P-type impurity layer is 6° or more and 10° or less.

15. The method of manufacturing a semiconductor device according to claim 11, wherein
the angle of inclination on the lateral side of the trench relative to the normal line at the surface of the low concentration P-type impurity layer is smaller than the angle of implanting the impurities into the low concentration P-type impurity layer relative to the normal line at the surface of the low concentration P-type impurity layer.

16. The method of manufacturing a semiconductor device according to claim 11, wherein
the low concentration P-type impurity layer is a silicon layer and B (boron) is used as the impurity.
